(19) United States
(12) Patent Application Publication
(10) Pub. No.: US 2026/0112435 A1
(43) Pub. Date: Apr. 23, 2026

(54) CURRENT-MODE PROGRAMMING CIRCUIT OF ONE-TIME PROGRAMMABLE (OTP) MEMORY AND CURRENT-MODE PROGRAMMING METHOD THEREOF

(71) Applicant: NATIONAL CHENG KUNG UNIVERSITY, Tainan City (TW)

(72) Inventors: Ming-Yan FAN, Tainan City (TW); Chen-An CHEN, Tainan City (TW); Hsiang-Yu KO, Tainan City (TW); Chih-Hao WANG, Tainan City (TW)

(21) Appl. No.: 19/363,313

(22) Filed: Oct. 20, 2025

Related U.S. Application Data
(60) Provisional application No. 63/709,532, filed on Oct. 21, 2024.

(30) Foreign Application Priority Data
May 8, 2025 (TW) 114117288

(51) Int. Cl. G11C 17/18; G11C 5/14; G11C 17/12; G11C 17/16

(52) U.S. Cl. CPC G11C 17/18; G11C 5/145; G11C 17/12; G11C 17/16

(57) ABSTRACT

A current-mode programming (CMP) circuit of one-time programmable memory (OTP) is disclosed. The CMP circuit has a constant current source and a closed-loop detector. The constant current source provides a sufficiently high programming current of rupturing a fuse of a bit cell of OTP selected by the logic control unit. The closed-loop detector monitors the programming current and determines whether the programming current is rapidly reduced when the fuse has been ruptured. Therefore, the CMP circuit successfully ruptures the fuse of the selected bit cell against process and temperature impacts thereon. Further, the closed-loop detector monitors the resistance transition of the selected bit cell and flags a successful programming signal in real time during each fuse-rupturing process.

### CROSS-REFERENCE TO RELATED APPLICATIONS

This application claims the benefit of United States provisional application filed on Oct. 21, 2024, and having application Ser. No. 63/709,532, the entire contents of which are hereby incorporated herein by reference.

This application is based upon and claims priority under 35 U.S.C. 119 from Taiwan Patent Application No. 114117288 filed on May 8, 2025, which is hereby specifically incorporated herein by this reference thereto.

### BACKGROUND OF THE INVENTION

### 1. Field of the Invention

The present invention relates to a current-mode programming circuit of one-time programmable (OTP) memory, and more particularly to a current-mode programming circuit of OTP memory.

### 2. Description of the Prior Arts

With reference to FIG. 8, a conventional one-time programmable (hereinafter OTP) memory 50 is shown and at least includes a memory array 51 with n*m bit cells 511, n word-line (hereinafter WL) drivers 52, m bit-line (hereinafter BL) drivers 53 and a logic control circuit 54. Each bit cell 511 is electrically connected to a constant voltage V_{PGM} through transistors 531 and includes a fuse 512 and a switch 513 connected in series. The fuse 512 is electrically connected between the transistor 531 and the switch 513. The transistor 531 is connected to the corresponding BL driver 53 and the switch 513 is connected to the corresponding WL driver 52. The BL drivers 53 and WL drivers 52 are connected to the logic control circuit 54 and the logic control circuit 54 selects anyone of the bit cells to program by controlling the BL driver 53 and WL driver 52 to turn on the transistor 531 and the switch 513. At the time, a conducting path is established between the constant voltage V_{PGM} and the selected bit cell 511, as shown in FIG. 9A. With further reference to FIG. 9B, a programming current I_{PGM} passes through the conducting path to rupture the fuse 512 of the selected bit cell 511 of FIG. 9A.

Using a metal fuse as an example, the successful programming of the selected bit cell relies on thermally accelerated electro-migration to physically rupture the metal fuse thereof. Once a voltage is applied across two ends of the metal fuse and an instantaneous, subsequent high current flow through the metal fuse generates a hotspot creating significant Joule heat within the metal fuse. The transient rise in temperature at the hotspot alters the resistance of the metal fuse and accelerates the formation of void. Once the void is formed, the metal fuse is successfully and physically ruptured.

As shown in FIG. 9B, the value of the programming current I_{PGM} depends on the ratio of the constant voltage V_{PGM} to the total resistance Rₜₒₜₐₗ in the conducting path, wherein Rₜₒₜₐₗ is sum of R_{fuse} and R_{M1}. To successfully rupture the metal fuse against process and temperature impacts on Rₜₒₜₐₗ, a sufficiently high constant voltage V_{PGM} is typically designed to generate a suitably high programming current I_{PGM}.

The voltage-mode programming (hereinafter VMP) scheme as mentioned above applies a constant voltage V_{PGM} to program the selected bit cell within a predefined programming time ranging from a few microseconds to tens of microseconds. During small-volume characterization, the lower bound of the constant voltage V_{PGM} is empirically obtained by measuring programming yields across different constant voltage V_{PGM} values, with each bit cell programmed within the predefined programming time. Nevertheless, a practical constant voltage V_{PGM} adopted in mass production is more likely to be higher than the minimum constant voltage V_{PGM} derived from small-scale prototyping. This additional margin in the constant voltage V_{PGM} is expected to bridge the gap or prevent discrepancies between small-volume prototyping and mass production. Therefore, this potentially leads to a higher constant voltage V_{PGM} that deteriorates over-stress risk but does not necessarily ensure a high programming yield due to the uncertain electrical characteristics of a fuse during each programming.

On-chip OTP memory employing the VMP scheme has at least three disadvantages: 1) designing bit cells based on worst-case of Rₜₒₜₐₗ scenario may lead to over-design and increase area overhead; 2) employing a high V_{PGM} raises concern of over-stress reliability; and 3) it is difficult to guarantee 100% programming yield in mass production, as the practical V_{PGM} adopted in mass production is often higher than the minimum value derived from small-scale prototyping.

To overcome the shortcomings, the present invention provides a current-mode programming circuit of OTP memory to mitigate or to obviate the aforementioned problems.

### SUMMARY

An objective of the present invention is to provide a current-mode programming (hereinafter CMP) circuit of OTP memory and a current-mode programming method thereof.

The OTP memory at least has a plurality of bit cells and a logic control unit and each bit cell has a fuse and a first switch electrically connected in serial. The control logic unit selects and turns on the first switch of one of the plurality of bit cells to program. The CMP circuit of OTP memory has:
a constant current source electrically connected to the plurality of bit cells and providing a programing current to the selected bit cell to rupture the fuse thereof; and
a closed-loop detector coupled to or electrically connected to the plurality of bit cells and electrically connected to the logic control unit, wherein the closed-loop detector monitors changes of the programming current passing through the selected bit cell, determines that the programming current is rapidly reduced due to the fuse of the selected bit cell being ruptured by monitoring the changes of the programming current and then outputs a successful programming signal configured to be output to the logic control unit to turn off the first switch of the selected bit cell.

Based on the foregoing description, the CMP circuit of the present invention uses the constant current source to provide the sufficient programming current of rupturing the fuse of the bit cell selected by the logic control unit. The fuse of the selected bit cell is successfully ruptured against process and temperature impacts thereon. Further, the CMP circuit, developed under the rapid and substantial resistance transition (differing by more than three orders of magnitude) with current-mode programming, enables bi-state resistance changes that induce two distinct current levels or voltage levels. The closed-loop detector distinguishes different current levels or different voltage levels accurately. Therefore, the closed-loop detector monitors the resistance transition of the selected bit cell. Further, the closed-loop detector flags the successful programming signal in real time during each fuse-rupturing process.

The CMP method of OTP memory in accordance with the present invention has steps of:
(a) selecting and turning on the first switch of one of the bit cells by the logic control unit to establish a conducting path between the selected bit cell and a constant current source;
(b) providing a programming current from the constant current source to pass through the selected bit cell via the conductive path, wherein the programming current is sufficiently high to rupture the fuse of the selected bit cell;
(c) monitoring and determining whether the programming current is rapidly reduced due to the fuse of the selected bit cell being ruptured; and
(d) turning off the first switch of the selected bit cell by the logic control unit when a determining result is positive to completely program the selected bit cell.

Based on the foregoing description, the CMP method of the present invention uses the constant current source to provide the sufficient programming current of rupturing the fuse of the bit cell selected by the logic control unit. The fuse of the selected bit cell is successfully ruptured against process and temperature impacts thereon. Since an initial resistance of the fuse and a resistance of the ruptured fuse differ by more than three orders of magnitude, the programming current is further monitored and accurately determined whether the fuse has been ruptured. In addition, a successful programming signal may be flagged in real time during each fuse-rupturing process.

Other objectives, advantages and novel features of the invention will become more apparent from the following detailed description when taken in conjunction with the accompanying drawings.

### BRIEF DESCRIPTION OF THE DRAWINGS

FIG. 1 is a functional block diagram of a first embodiment of a CMP circuit of OTP memory in accordance with the present invention;

FIG. 2 a signal waveform diagram of FIG. 1;

FIG. 3 is a functional block diagram of a second embodiment of a CMP circuit of OTP memory in accordance with the present invention;

FIG. 4 is a functional block diagram of a third embodiment of a CMP circuit of OTP memory in accordance with the present invention;

FIG. 5 a signal waveform diagram of FIG. 4;

FIG. 6 is a flow chart of CMP method of OTP memory in accordance with the present invention;

FIG. 7 is a comparison of the minimum programming voltages in prior fuse technologies;

FIG. 8 is a VMP circuit of OTP memory in accordance with the prior art;

FIG. 9A is sampled circuit diagram of one bit cell of FIG. 8; and

FIG. 9B is an equivalent circuit diagram of FIG. 9B.

### DETAILED DESCRIPTION OF THE EMBODIMENTS

The embodiments of the present disclosure are discussed in detail below. However, it is understood that the embodiments provide many applicable concepts that may be implemented in various specific contexts. The embodiments discussed and disclosed herein are merely for illustration and are not intended to limit the scope of the present disclosure. The terms “first,” “second,” and so on, as used herein, do not indicate any particular order or priority, but are merely used to distinguish elements or operations described by the same technical terms.

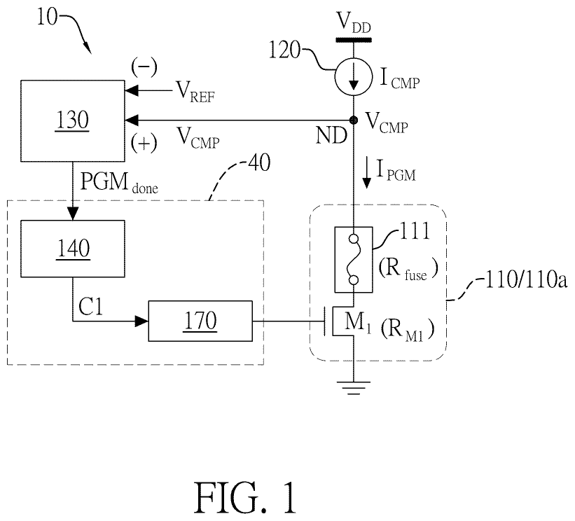

With reference to FIG. 1, a first embodiment of a CMP circuit of OTP memory 10 in accordance with the present invention is illustrated. The OTP memory 10 at least has a plurality of bit cells 110 (FIG. 1 shows one of them) and a logic control unit 40. Each bit cell 110 has a fuse 111 and a first switch M1 electrically connected in serial. The control logic unit 40 selects and turns on the first switch M1 of one of the plurality of bit cells 110 to program. In the present embodiment, the logic control unit 40 has a logic control circuit 140 and a plurality of word-line (WL) drivers 170 (FIG. 1 shows one of them). Particularly, the logic control circuit 140 outputs a first control signal C1 to turn on or off the first switch M1 of the selected bit cell 110 through the WL driver 170.

The CMP circuit programs one of the bit cells 110a selected by the logic control unit 40 and has a constant current source 120 and a closed-loop detector 130. The constant current source 120 is electrically connected to the plurality of bit cells 110 and provides a programing current I_{PGM} to the selected bit cell 110a to rupture the fuse 111 thereof. In the present embodiment, when the logic control circuit 140 turns on the first switch M1 of the selected bit cell 110a through the WL driver 170, a conducting path between the constant current source 120 and the selected bit cell 110a is established. Therefore, the programing current I_{PGM} from the constant current source 120 passes through the fuse 111 and the turn-on first switch M1 of the selected bit cell 110a. In one embodiment, the constant current source 120 may be an adjustable constant current source providing different constant currents for the integrated circuit designer to select a suitable one of the constant currents.

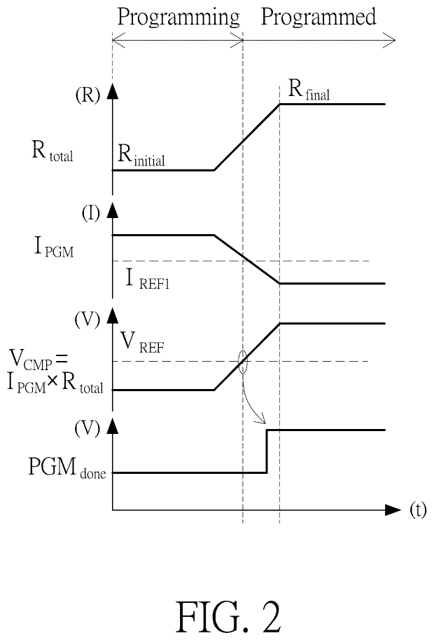

With reference to FIG. 2, a total resistance Rₜₒₜₐₗ of the conducting path of FIG. 1 is sum of a fuse resistance R_{fuse} and a resistance R_{M1} of the turn-on first switch M1 of FIG. 1. The first switch M1 may be an NFET or the like that may be implemented on chip. Since the programming current I_{PGM} is sufficiently high to successfully rupture the fuse 111 against process and temperature impacts on the total resistance Rₜₒₜₐₗ, the total resistance Rₜₒₜₐₗ has a rapid and substantial resistance transition from Rᵢₙᵢₜᵢₐₗ to R_{final} after a few nanoseconds to microseconds. A resistance of the ruptured fuse 111 R_{final} is larger than an initial resistance of the fuse 111 Rᵢₙᵢₜᵢₐₗ and they are differing by more than three orders of magnitude. During the resistance transition, the programming current I_{PGM} is relatively and rapidly reduced. According to Ohm's Law, a voltage V_{CMP} at a connection node ND between the constant current source 120 and the selected bit cell 110a is rapidly increased accordingly. Therefore, the CMP circuit enables bi-state resistance changes that induce two distinct current levels or voltage levels.

With reference to FIG. 1, the closed-loop detector 130 is coupled to or electrically connected to the plurality of bit cells 110 (FIG. 1 shows one of them) and electrically connected to the logic control unit 40. The closed-loop detector 130 monitors changes of the programming current I_{PGM} passing through the selected bit cell 110a, determines that the programming current I_{PGM} is rapidly reduced due to the fuse 111 of the selected bit cell 110a being ruptured by monitoring the changes of the programming current I_{PGM} and then outputs a successful programming signal PGM_{done} configured to be output to the logic control unit 140 to turn off the first switch M₁ of the selected bit cell 110a.

In the present embodiment, the closed-loop detector 130 is electrically connected to the plurality of bit cells 110 and the logic control circuit 140 of the logic control unit 40. The closed-loop detector 130 may be a voltage comparator, such as Hysteresis comparator or the like that can be implemented on chip. The voltage comparator 130 has a first input electrically connected to a reference voltage V_{REF}, a second input electrically connected to the connection node ND to detect changes of a voltage V_{CMP} at the connection node ND according to changes of the programing current I_{PGM} and an output electrically connected to the logic control circuit 140 of the logic control unit 40. The voltage comparator 130 compares the changes of the voltage V_{CMP} at the connection node ND with the reference voltage V_{REF} and outputs the comparison signal PGM_{done} to the logic control circuit 140 of the logic control unit 40.

With further reference to FIG. 2, since the voltage V_{CMP} at the connection node ND is rapidly increased when the fuse 111 is ruptured by the programming current I_{PGM}. To determine that the programming current I_{PGM} is rapidly reduced due to the fuse 111 of the selected bit cell 110a being ruptured, the reference voltage V_{REF} is further preset between the minimum to the maximum of the voltage V_{CMP}. In one embodiment, the second input of the voltage comparator 130 is a positive input of the voltage comparator electrically connected to the connection node ND. When the voltage V_{CMP} at the connection node ND is larger than the reference voltage V_{REF}, a voltage level of the comparison signal PGM_{done} changes from low to high to determine that the programming current I_{PGM} is rapidly reduced due to the fuse 111 of the selected bit cell 110a being ruptured. Since the comparison signal PGM_{done} is outputted to the logic control circuit 140, the logic control circuit 140 of the logic control unit 40 immediately determines that the fuse 111 of the selected bit cell 110a has been ruptured according to the comparison signal PGM_{done}. And then, the logic control circuit 140 of the logic control unit 40 outputs the first control signal C1 to the first switch M1 to turn off the first switch M1 through the corresponding WL driver 170. The programming of the selected bit cell 110a is completed.

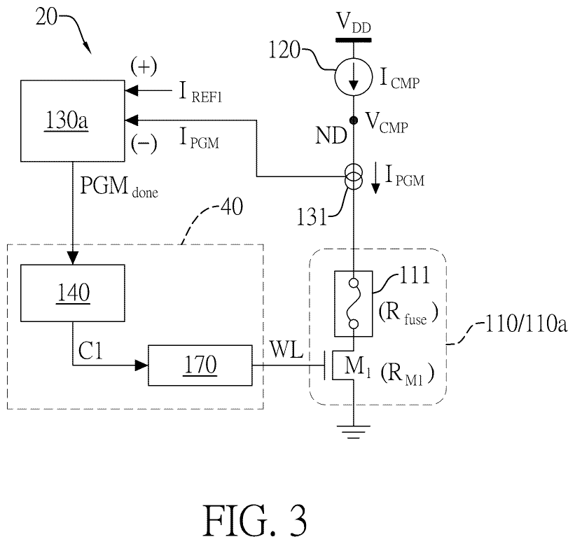

With reference to FIG. 3, a second embodiment of a CMP circuit of OTP memory 20 in accordance with the present invention is illustrated and is similar to the first embodiment of FIG. 1. In the present embodiment, the closed-loop detector 130a is coupled to the plurality of bit cells 110 (FIG. 3 shows one of them) and electrically connected to the logic control circuit 140 of the logic control unit 40.

The closed-loop detector 130a may be a current comparator that can be implemented on chip. The current comparator 130a has a first input, a second input and an output. The first input is electrically connected to a reference current I_{REF1}, a second input is coupled to the conducting path through a current sensor 131 to detect the changes of the programming current I_{PGM}. The output is electrically connected to the logic control circuit 140 of the logic control unit 40. The current comparator 130a compares the changes of the programming current I_{PGM} and the current reference I_{REF1} and outputs the comparison signal PGM_{done} to the logic control circuit 140 of the logic control unit 40.

With further reference to FIG. 3, since the programming current I_{PGM} passing through the conducting path is rapidly reduced when the fuse 111 is ruptured, the reference current I_{REF1} is preset between the minimum to the maximum current of the programming current I_{PGM}. In one embodiment, the second input of the current comparator is a negative input of the current comparator electrically connected to the current sensor 131. When the programming current I_{PGM} is less than the reference current I_{REF1}, a voltage level of the comparison signal PGM_{done} changes from low to high to determine that the programming current I_{PGM} is rapidly reduced due to the fuse 111 of the selected bit cell 110a being ruptured. The logic control circuit 140 of the logic control unit 40 outputs the first control signal C1 to the first switch M1 to turn off the first switch M1 through the corresponding WL driver 170. The programming of the selected bit cell 110 is completed.

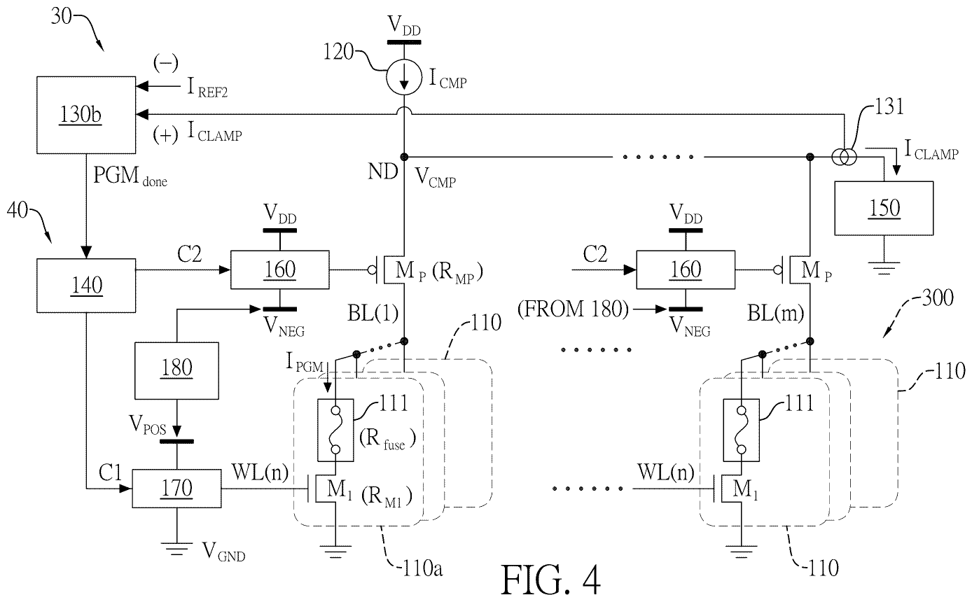

With reference to FIG. 4, a third embodiment of a CMP circuit of OTP memory 30 in accordance with the present invention is illustrated and is similar to the second embodiment of the CMP circuit. In the present embodiment, the CMP circuit further has a voltage clamper 150 electrically connected to the connection node ND. Therefore, when one of the bit cells 110a is selected by the logic control unit 40 and the conducting path is established, a constant current I_{CMP} from the constant current source 120 is a sum of the programming current I_{PGM} and a current I_{CLAMP} of the voltage clamper 150. Therefore, the current I_{CLAMP} of the voltage clamper 150 changes according to changes of the programing current I_{PGM}. Thus, the closed-loop detector 130b monitors changes of the programming current passing through the selected bit cell by detecting changes of the current I_{CLAMP} of the voltage clamper 150. Particularly, the second input of the current comparator 130b is coupled to a current path of the voltage clamper 150 to detect changes of the current I_{CLAMP} of the voltage clamper 150.

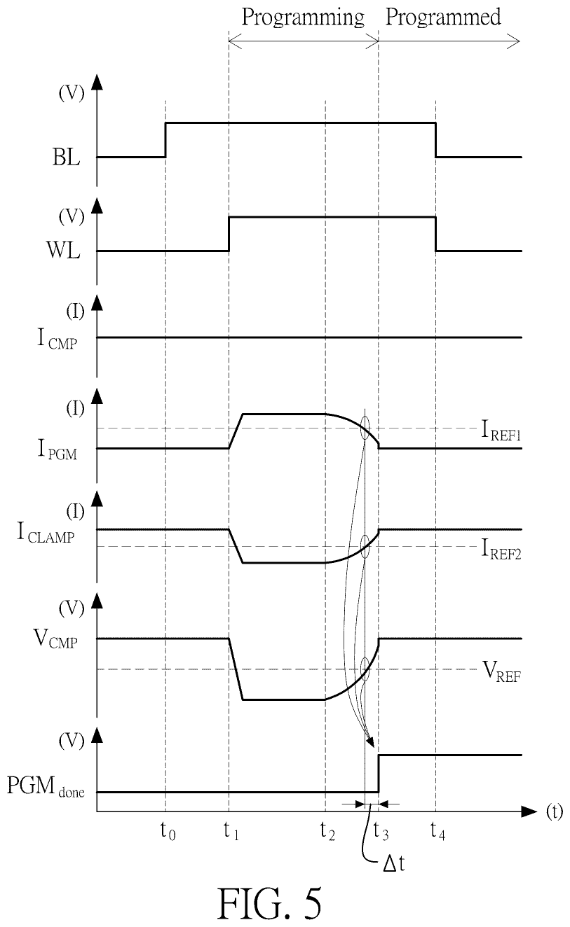

With further reference to FIG. 5, since the constant current source 120 provides the constant current I_{CMP}, when the fuse 111 of the selected bit cell 110a is ruptured by the programming current I_{PGM}, the programming current I_{PGM} is rapidly reduced but the current I_{CLAMP} of the voltage clamper 150 is rapidly increased to clamp a fixed level of the voltage V_{PGM} at the connection node ND. Therefore, the closed-loop detector 130b also monitors the changes of the programming current I_{PGM} by detecting the changes of the current I_{CLAMP} of the voltage clamper 150.

Particularly, to further determine the rapid reduction of the programing current I_{PGM} due to the fuse 111 of the selected bit cell 110a being ruptured, the reference current I_{REF2} is preset between the minimum to maximum of the current I_{CLAMP} of the voltage clamper 150. In one embodiment, the second input of the current comparator 130b is a positive input of the current comparator 130b electrically connected to the current sensor 131. When the current I_{CLAMP} of the voltage clamper 150 is higher than the reference current I_{REF2}, a voltage level of the comparison signal PGM_{done} changes from low to high to determine that the programming current I_{PGM} is rapidly reduced due to the fuse 111 of the selected bit cell 110a being ruptured. Therefore, the logic control circuit 140 of the logic control unit 40 outputs the first control signal C1 to the first switch M₁ to turn off the first switch M₁ through the corresponding WL driver 170. The programming of the selected bit cell 110a is completed. In addition, the voltage clamper 150 may also be employed in the first and second embodiments of the CMP circuits.

In the third embodiment, the plurality of the bit cells 110 are further arranged in a n*m memory array 300. That is, each column of the n*m memory array 300 has n bit cells 110 and the logic control unit has n WL drivers 170. Each WL driver 170 is electrically connected to the m first switches M₁ of the m bit cells 110 on the corresponding row. Each row of the n*m memory array 300 has m bit cells 110 and the logic control unit 40 further has m second switches M_{P} and m bit-line (BL) drivers 160. The m second switches M_{P} are respectively and electrically connected between the m columns of the n*m memory array 300 and the constant current source 120. The m BL drivers 160 are respectively and electrically connected to the m second switches M_{P} and the logic control circuit 140. Therefore, the logic control unit 40 selects one of the plurality of the bit cells 110a through controlling the corresponding WL driver 170 and BL driver 160 to turn on the first and second switches M₁, M_{P}, respectively. In FIG. 4, the bit cell 110a located at (n, 1) of the n*m memory array 300 is selected. When the first and second switches M₁, M_{P} are turned on, a conducting path is established between the constant current source 120 and the selected bit cell 110a. That is, the selected bit cell 110a is electrically connected to the constant current source 120 through the corresponding second switch M_{P}, such as a field-effect transistor or the like that may be implemented on chip. Therefore, a total resistance Rₜₒₜₐₗ of the conducting path is a sum of the fuse resistance R_{fuse}, the resistance R_{M1} of the first switch M₁ and a resistance R_{MP} of the second switch M_{P}.

For on-chip OTP memory 30, a system power is used and the system power has a positive voltage V_{DD} and a ground voltage V_{GND}. In the third embodiment, the CMP circuit may further have a charge pump 180. The charge pump 180 is configured to generate a negative voltage V_{NEG} to m negative power supply voltage input terminals of the BL drivers 160, wherein V_{NEG}<V_{GND} (0V). The charge pump 180 is also configured to generate a positive voltage V_{POS} to n positive power supply voltage input terminals of the WL drivers 170, wherein V_{POS}>V_{DD}. The positive voltage V_{DD} of the system power is also provided to m positive power supply voltage input terminals of the BL drivers 160. The ground voltage V_{GND} of the system power is also provided to n negative power supply voltage input terminals of the WL drivers 170. The negative voltage V_{NEG} generated by the charge pump 180 can be used to reduce a resistance R_{MP} of the field-effect transistor M_{P}. The positive voltage V_{POS} generated by the charge pump 180 can be used to reduce the resistance R_{M1} of the field-effect transistor M₁. Therefore, the positive voltage V_{DD} of the system power is further reduced by the charge pump 180, enabling low-voltage operation.

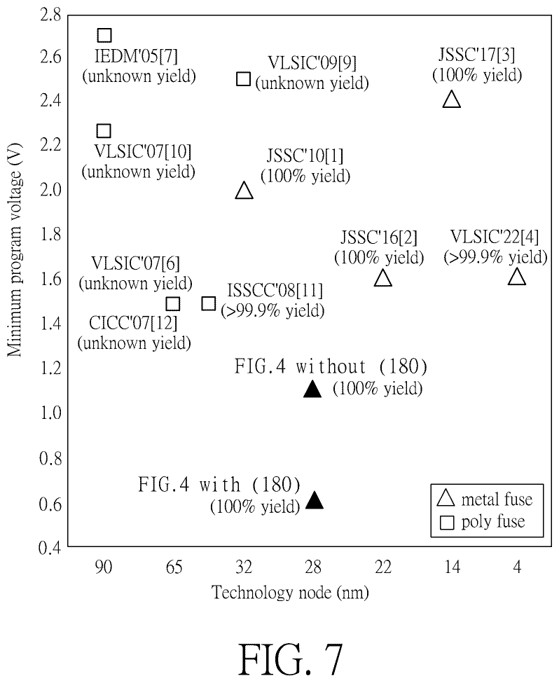

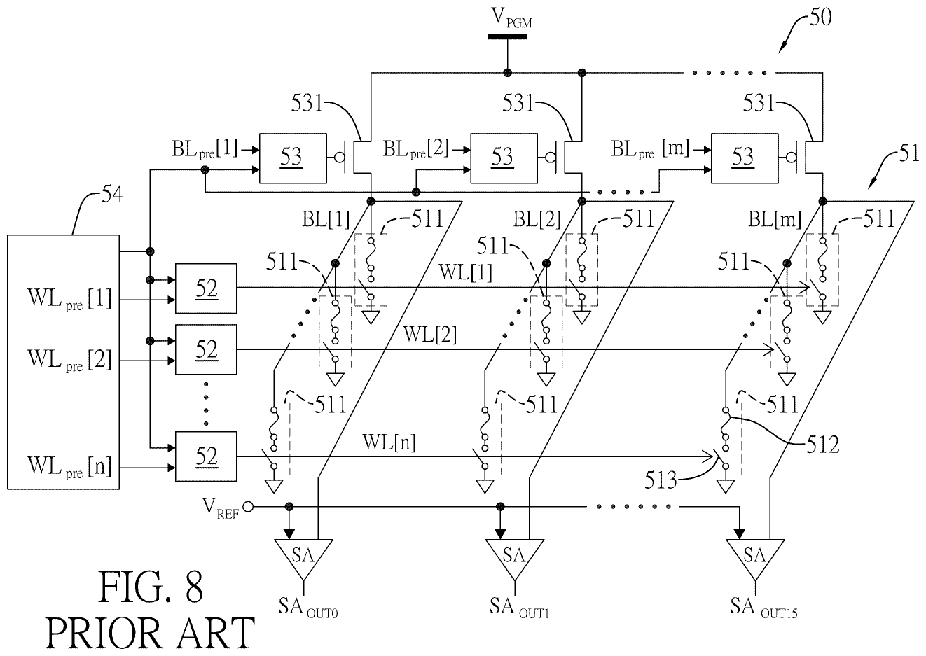

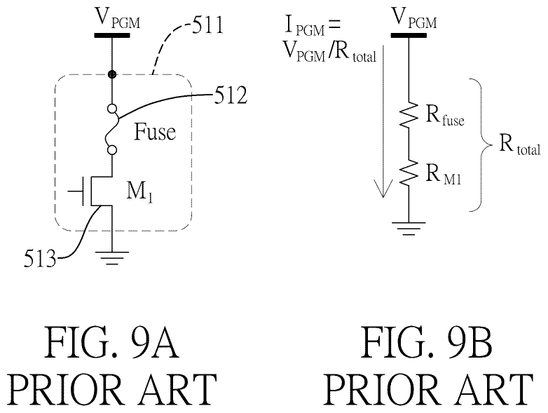

With reference to FIG. 7, an OTPROM (marked by “FIG. 4 without (180)”) with the CMP circuit of FIG. 4 without the charge pump 180 is implemented on chip in 28 nm CMOS technology, the voltage V_{CMP} can be achieved 1.1V. Another OTPROM (marked by “FIG. 4 with (180)”) with the CMP circuit of FIG. 4 with the charge pump 180 is implemented on chip in 28nm CMOS technology, the voltage V_{CMP} is largely reduced to 0.6V. Compared to a conventional OTPROM (marked by “JSSC′16[2]”) with VMP circuit of FIG. 8 implemented on chip in 22 nm COMS technology, the programming voltage V_{PGM} is not less than 1.6V. Therefore, designing bit cells of the present invention based on worst-case of Rₜₒₜₐₗ scenario may not lead to over-design.

With reference to FIGS. 4 and 5, when a bit cell on (n, 1) of the n*m memory array 300 is selected to program, the logic control circuit 140 outputs the control signals C1 and C2 to the nth WL driver 170 and the first BL driver 160 to respectively turn on the first and second switches M₁, M_{P} of the selected bit cell 100a at the time t₁ and the time t₀. When both of the first and second switches M₁, M_{P} are turned on at the time t₁, the selected bit cell 110a starts to program, a conducting path is established. At the time, the total resistance Rₜₒₜₐₗ of the conducting path is a lower resistance Rᵢₙᵢₜᵢₐₗ, as shown in FIG. 2. Therefore, the programming current I_{PGM} passing through the conducting path with the lower resistance Rᵢₙᵢₜᵢₐₗ is increased to a fixed high value, but the current I_{CLAMP} of the voltage clamper 150 and the voltage V_{CMP} at the connection node ND are relatively reduced to a fixed low value from the time t₁ to the time t₂.

From the time t₁ to the time t₂, the programming current I_{PGM} with the fixed high value flows through the fuse 111 of the selected bit cell 110a, a significant Joule heat is created within the fuse 111 to form a hotspot. After the time t₂, the transient rise in temperature at the hotspot alters the fuse resistance R_{fuse} and accelerates the formation of void. During forming the void defining through the fuse 111, the total resistance Rₜₒₜₐₗ of the conducting path is increasing from the lower Rᵢₙᵢₜᵢₐₗ to a higher R_{final}, as shown in FIG. 2, the programming current I_{PGM} is rapidly reduced, but the current I_{CLAMP} of the voltage clamper 150 and the voltage V_{CMP} at the connection node ND are relatively and rapidly increased.

When the voltage V_{CMP} at the connection node ND is increased to be larger than the reference voltage V_{REF} at a time (t₃−Δt), the voltage comparator 130 of FIG. 1 may be used to determine that the voltage V_{CMP} is larger than the reference voltage V_{REF}. After a short delay time Δt, the voltage comparator 130 outputs the comparison signal PGM_{done} at the time t₃. At the time t₃, the fuse 111 has been ruptured and the selected bit cell 110a of FIG. 4 is completely programmed. And then, the logic control unit 40 turns off the nth WL driver 170 and the first BL driver 160 at the time t₄. That is, the closed-loop detector 130 flags a successful programming signal in real time during each fuse-rupturing process. At the time, the selected bit cell 110a is disconnected from the constant current source I_{CMP}, resulting in I_{PGM}≈0 and the voltage clamper 150 protects the rest of the bit cells 110 by absorbing nearly all I_{CMP} (i.e. I_{CLAMP}≈I_{CMP}).

In another case, when the programming current I_{PGM} is reducing to be less than the reference current I_{REF1} at the time (t₃−Δt), the current comparator 130a of FIG. 3 may be used to determine that the programming current I_{PGM} is less than the reference current I_{REF1}. After the short delay time Δt, the current comparator 130a outputs the comparison signal PGM_{done} at the time t₃. At the time t₃, the fuse 111 has been ruptured and the selected bit cell 110a is completely programmed. And then, the logic control unit turns off the nth WL driver 170 and the first BL driver 160 at the time t₄.

In another case, when the current I_{CLAMP} of the voltage clamper 150 is increased to be larger than the reference current I_{REF2} at the time (t₃−Δt), the current comparator 130b of FIG. 4 is used to determine that the current I_{CLAMP} of the voltage clamper 150 is larger than the reference current I_{REF2}. After the short delay time Δt, the current comparator 130b outputs the comparison signal PGM_{done} at the time t₃. At the time t₃, the fuse 111 has been ruptured and the selected bit cell 110a is completely programmed. And then, the logic control unit turns off the nth WL driver 170 and the first BL driver 160 at the time t₄.

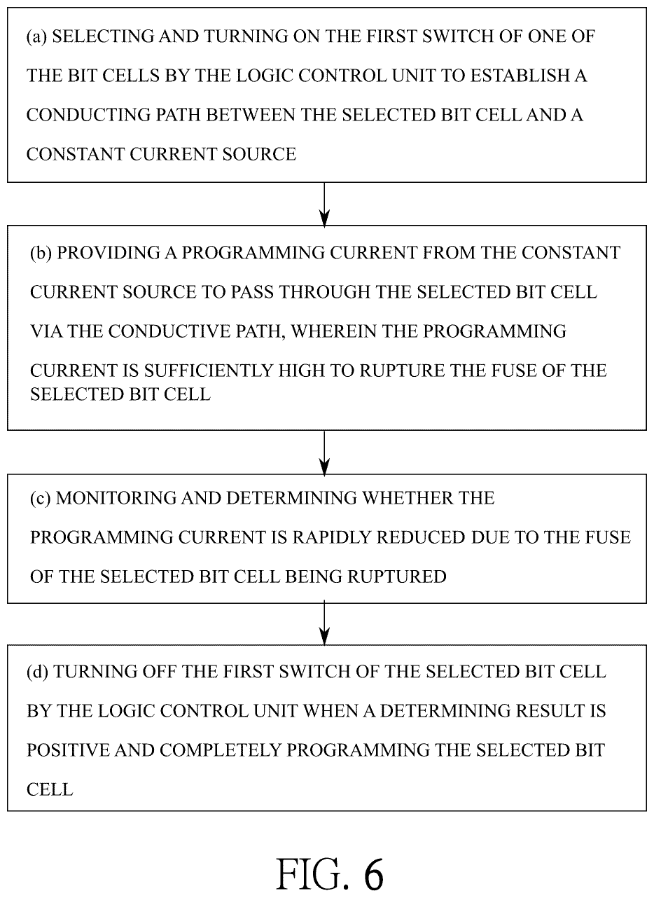

Based on the first to third embodiments of the CMP circuits for OTP memory, a CMP method of OTP memory includes steps (a) to (d), as shown in FIG. 6.

In the step (a), with reference to FIGS. 1 and 3, to program one of the bit cells 110a, a first switch M₁ of selected bit cell 110a is turned on by the logic control unit 40 to establish a conducting path between the selected bit cell 110a and a constant current source 120. In FIG. 4, a second switch M_{P} electrically to the selected bit cell 110a is further turned on by the logic control unit 40.

In the step (b), as shown in FIGS. 1, 3 and 4, the constant current source 120 provides a programming current I_{PGM} to pass through the selected bit cell 110a via the conductive path to rupture the fuse 111 of the selected bit cell 110a. The programming current I_{PGM} is sufficiently high to rupture the fuse 111 of the selected bit cell 110a.

In the step (c), as shown in FIGS. 1, 3 and 4, the programming current I_{PGM} is monitored to be determined whether the programming current I_{PGM} is rapidly reduced due to the fuse being ruptured. In FIG. 1, the programming current I_{PGM} is monitored by monitoring a voltage V_{CMP} at a connection node ND of the constant current source 120 and the selected bit cell 110a. When the voltage V_{CMP} at the connection node ND is larger than a reference voltage V_{REF}, it is determined that the programming current I_{PGM} is rapidly reduced. In FIG. 3, the programming current I_{PGM} is directly monitored. When the programming current I_{PGM} is less than a reference current I_{REF1}, it is determined that the programming current I_{PGM} is rapidly reduced, too. In FIG. 4, the programming current I_{PGM} is monitored by monitoring a current I_{CLAMP} of the voltage clamper 150. When the current I_{CLAMP} of the voltage clamper 150 is larger than a reference voltage I_{REF2}, it is determined that the programming current I_{PGM} is rapidly reduced.

In the step (d), the first switch M₁ of the selected bit cell 110a of FIGS. 1 and 3 is turned off by the logic control unit 40 when a determining result of the step (c) is positive and the selected bit cell is completely programmed. In FIG. 4, the second switch M_{P} electrically connected to the selected bit cell 110a is further turned off by the logic control unit 40.

Based on the foregoing description, the CMP circuit and the CMP method of OTP memory in accordance with the present invention uses the constant current source to provide the sufficiently high programming current of rupturing the fuse of the bit cell selected by the logic control unit. The fuse of the selected bit cell is successfully ruptured against process and temperature impacts thereon. Further, the CMP circuit, developed under the rapid and substantial resistance transition (differing by more than three orders of magnitude) with current-mode programming, enables bi-state resistance changes that induce two distinct current levels or voltage levels. The closed-loop detector distinguishes different current levels or different voltage levels accurately. Therefore, the closed-loop detector monitors the resistance transition of the selected bit cell. Further, the closed-loop detector flags the successful programming signal in real time during each fuse-rupturing process.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A current-mode programming (CMP) circuit of OTP memory, wherein the OTP memory includes a plurality of bit cells and a logic control unit, each of the plurality of bit cells has a fuse and a first switch connected in serial and the control logic unit selects and turns on the first switch of one of the plurality of bit cells to program, wherein the CMP circuit comprising:
a constant current source configured to be electrically connected to the plurality of bit cells and providing a programing current to the selected bit cell to rupture the fuse thereof; and
a closed-loop detector coupled to or electrically connected to the plurality of bit cells and electrically connected to the logic control unit, wherein the closed-loop detector monitors changes of the programming current passing through the selected bit cell, determines that the programming current is rapidly reduced due to the fuse of the selected bit cell being ruptured by monitoring the changes of the programming current and then outputs a successful programming signal configured to be output to the logic control unit to turn off the first switch of the selected bit cell.

2. The CMP circuit of OTP memory as claimed in claim 1, wherein the closed-loop detector is a voltage comparator comprising:
a first input electrically connected to a reference voltage;
a second input electrically connected to a connection node of the constant current source and the plurality of the bit cells to detect changes of a voltage at the connection node according to changes of the programing current; and
an output outputting the successful programming signal according to a comparison signal between the detected voltage at the connection node and the reference voltage.

3. The CMP circuit of OTP memory as claimed in claim 1, wherein the closed-loop detector is a current comparator comprising:
a first input electrically connected to a reference current;
a second input coupled to a current path of the programming current to detect the changes of the programming current; and
an output outputting the successful programming signal according to a comparison signal between the detected programming current and the reference current.

4. The CMP circuit of OTP memory as claimed in claim 1, further comprising a voltage clamper electrically connected to a connection node of the constant current source and the plurality of the bit cells, wherein a constant current of the constant current source is a sum of the programming current and a current of the voltage clamper.

5. The CMP circuit of OTP memory as claimed in claim 2, further comprising a voltage clamper electrically connected to a connection node of the constant current source and the plurality of the bit cells, wherein a constant current of the constant current source is a sum of the programming current and a current of the voltage clamper.

6. The CMP circuit of OTP memory as claimed in claim 3, further comprising a voltage clamper electrically connected to a connection node of the constant current source and the plurality of the bit cells, wherein a constant current of the constant current source is a sum of the programming current and a current of the voltage clamper.

7. The CMP circuit of OTP memory as claimed in claim 4, wherein the closed-loop detector is a current comparator comprising:
a first input electrically connected to a reference current;
a second input coupled to a current path of the current of the voltage clamper to detect changes of the current of the voltage clamper; and
an output outputting the successful programming signal according to a comparison signal between the detected current of the voltage clamper and the reference current.

8. The CMP circuit of OTP memory as claimed in claim 4, wherein
the plurality of bit cells are arranged in a n*m memory array; and
the logic control unit further comprises:
n word-line (WL) drivers each of which is electrically connected to the first switches of the m bit cells on the corresponding row of the n*m memory array;
m second switches respectively and electrically connected between the m columns of the n*m memory array and the constant current source;
m bit-line (BL) drivers respectively and electrically connected to the m second switches; and
a logic control circuit electrically connected to the closed-loop detector, the n WL drivers and the m BL drivers.

9. The CMP circuit of OTP memory as claimed in claim 5, wherein
the plurality of bit cells are arranged in a n*m memory array;
the logic control unit further comprises:
n word-line (WL) drivers each of which is electrically connected to the first switches of the m bit cells on the corresponding row of the n*m memory array;
m second switches respectively and electrically connected between the m columns of the n*m memory array and the constant current source, wherein the second input of the voltage comparator is electrically connected to a connection node of the constant current source and the second switch;
m bit-line (BL) drivers respectively and electrically connected to the m second switches; and
a logic control circuit electrically connected to the output of the voltage comparator, the n WL drivers and the m BL drivers.

10. The CMP circuit of OTP memory as claimed in claim 6, wherein
the plurality of bit cells are arranged in a n*m memory array;
the logic control unit further comprises:
n word-line (WL) drivers each of which is electrically connected to the first switches of the m bit cells on the corresponding row of the n*m memory array;
m second switches respectively and electrically connected between the m columns of the n*m memory array and the constant current source;
m bit-line (BL) drivers respectively and electrically connected to the m second switches; and
a logic control circuit electrically connected to the output of the current comparator, the n WL drivers and the m BL drivers.

11. The CMP circuit of OTP memory as claimed in claim 7, wherein
the plurality of bit cells are arranged in a n*m memory array;
the logic control unit further comprises:
n word-line (WL) drivers each of which is electrically connected to the first switches of the m bit cells on the corresponding row of the n*m memory array;
m second switches respectively and electrically connected between the m columns of the n*m memory array and the constant current source, wherein the voltage clamper is electrically connected to a connection node of the constant current source and the second switches;
m bit-line (BL) drivers respectively and electrically connected to the m second switches; and
a logic control circuit electrically connected to the output of the current comparator, the n WL drivers and the m BL drivers.

12. The CMP circuit of OTP memory as claimed in claim 8, further comprising a system power and a charge pump configured to generate a negative voltage and a positive voltage, wherein
the constant current source is connected to a positive voltage of the system power;
each of the m BL drivers has
a positive power supply voltage input terminal connected to the positive voltage of the system power; and
a negative power supply voltage input terminal connected to the negative voltage from the charge pump, wherein the negative voltage from the charge pump is lower than a ground voltage of the system power; and
each of the n WL drivers has
a positive power supply voltage input terminal connected to the positive voltage from the charge pump, wherein the positive voltage from the charge pump is larger than the positive voltage of the system power; and
a negative power supply voltage input terminal connected to the ground voltage of the system power.

13. The CMP circuit of OTP memory as claimed in claim 9, further comprising a system power and a charge pump configured to generate a negative voltage and a positive voltage, wherein
the constant current source is connected to a positive voltage of the system power;
each of the m BL drivers has
a positive power supply voltage input terminal connected to the positive voltage of the system power; and
a negative power supply voltage input terminal connected to the negative voltage from the charge pump, wherein the negative voltage from the charge pump is lower than a ground voltage of the system power; and
each of the n WL drivers has
a positive power supply voltage input terminal connected to the positive voltage from the charge pump, wherein the positive voltage from the charge pump is larger than the positive voltage of the system power; and
a negative power supply voltage input terminal connected to the ground voltage of the system power.

14. The CMP circuit of OTP memory as claimed in claim 10, further comprising a system power and a charge pump configured to generate a negative voltage and a positive voltage, wherein
the constant current source is connected to a positive voltage of the system power;
each of the m BL drivers has
a positive power supply voltage input terminal connected to the positive voltage of the system power; and
a negative power supply voltage input terminal connected to the negative voltage from the charge pump, wherein the negative voltage from the charge pump is lower than a ground voltage of the system power; and
each of the n WL drivers has
a positive power supply voltage input terminal connected to the positive voltage from the charge pump, wherein the positive voltage from the charge pump is larger than the positive voltage of the system power; and
a negative power supply voltage input terminal connected to the ground voltage of the system power.

15. The CMP circuit of OTP memory as claimed in claim 11, further comprising a system power and a charge pump configured to generate a negative voltage and a positive voltage, wherein
the constant current source is connected to a positive voltage of the system power;
each of the m BL drivers has
a positive power supply voltage input terminal connected to the positive voltage of the system power; and
a negative power supply voltage input terminal connected to the negative voltage from the charge pump, wherein the negative voltage from the charge pump is lower than a ground voltage of the system power; and
each of the n WL drivers has
a positive power supply voltage input terminal connected to the positive voltage from the charge pump, wherein the positive voltage from the charge pump is larger than the positive voltage of the system power; and
a negative power supply voltage input terminal connected to the ground voltage of the system power.

16. The CMP circuit of OTP memory as claimed in claim 8, wherein
each of the first switches is a field-effect transistor; and
each of the second switches is a field-effect transistor.

17. A CMP method of OTP memory, wherein the OTP memory includes a plurality of bit cells and a logic control unit, each of the plurality of bit cells has a fuse and a first switch connected in serial and selects and the control logic unit selects and turns on the first switch of one of the plurality of bit cells to program, wherein the CMP circuit comprising steps of:
(a) selecting and turning on the first switch of one of the bit cells by the logic control unit to establish a conducting path between the selected bit cell and a constant current source;
(b) providing a programming current from the constant current source to pass through the selected bit cell via the conductive path, wherein the programming current is sufficiently high to rupture the fuse of the selected bit cell;
(c) monitoring and determining whether the programming current is rapidly reduced due to the fuse of the selected bit cell being ruptured; and
(d) turning off the first switch of the selected bit cell by the logic control unit when a determining result is positive and completely programming the selected bit cell.

18. The CMP method of OTP memory as claimed in claim 17, wherein the step (c) further comprises acts of:
(c1) detecting changes of a voltage at a connection node of the constant current source and the selected bit cell;
(c2) determining whether the detected voltage at the connection node is larger than a reference voltage; and
(c3) determining that the programming current is rapidly reduced if the voltage at the connection node is larger than the reference voltage.

19. The CMP method of OTP memory as claimed in claim 17, wherein the step (c) further comprises acts of:
(c1) detecting changes of the programming current passing through the conducting path;
(c2) determining whether the detected programming current is less than a reference current; and
(c3) determining that the programming current is rapidly reduced if the programming current is less than the reference current.

20. The CMP method of OTP memory as claimed in claim 17, further comprising a voltage clamper electrically connected to a connection node of the constant current source and the plurality of the bit cells, wherein a constant current of the constant current source is a sum of the programming current and a current of the voltage clamper, wherein the step (c) further comprises acts of:
(c1) detecting changes of the current of the voltage clamper;
(c2) determining whether the detect current of the voltage clamper is larger than a reference current; and
(c3) determining that the programming current is rapidly reduced if the current of the voltage clamper is larger than a reference current.
